(19) United States
(12) Patent Application Publication
(10) Pub. No.: US 2024/0077594 A1
(43) Pub. Date: Mar. 7, 2024

(54) OPTICAL PHASE ARRAY ANTENNA BASED ON OPTICAL WAVEGUIDE TYPE WITH HYBRID GRATING STRUCTURE AND LIDAR INCLUDING THE SAME

(71) Applicant: GIST (Gwangju Institute of Science and Technology), Gwangju (KR)

(72) Inventors: Nan Ei YU, Gwangju (KR); Byeong Chan PARK, Gwangju (KR)

(73) Assignee: GIST (Gwangju Institute of Science and Technology), Gwangju (KR)

(21) Appl. No.: 18/147,592

(22) Filed: Dec. 28, 2022

(30) Foreign Application Priority Data
Sep. 2, 2022 (KR) 10-2022-0111547

(51) Int. Cl. G01S 7/4915; G01S 7/4913; G03F 7/20

(52) U.S. Cl. CPC G01S 7/4915; G01S 7/4913; G03F 7/2037

(57) ABSTRACT

Provided is an optical phase array antenna including a coupling unit for receiving light from a light source, a light distribution unit for distributing light propagated from the coupling unit to a plurality of optical paths, a phase modulation unit for modulating a phase of the light distributed from the light distribution unit, and a light output unit that outputs the light modulated by the phase modulation unit, and includes an antenna element waveguide extending at a predetermined length through which the light propagates, and a clad layer formed to surround the antenna element waveguide, in which the antenna element waveguide has a first recessed portion recessed downward with respect to an upper surface thereof, and the clad layer has a second recessed portion recessed downward with respect to an upper surface thereof at a position adjacent to the first recessed portion.

### CROSS-REFERENCE TO RELATED APPLICATIONS

This application claims the priority of Korean Patent Application No. 10-2022-0111547 filed on Sep. 2, 2022, in the Korean Intellectual Property Office, the disclosure of which is incorporated herein by reference.

### BACKGROUND OF THE INVENTION

### Field of the Invention

The present disclosure relates to an optical phase array antenna based on an optical waveguide type with a hybrid grating structure and LIDAR including the same.

### Description of the Related Art

A LIDAR sensor for autonomous vehicles acquires 3D spatial information by measuring a time taken when an incident pulse laser is reflected from an object and returns. Depending on a laser emission method, the LIDAR sensor is largely divided into a ‘flash type’ and a ‘scanning type’. The flash type is a method of simultaneously scanning a laser beam to a large area, and a light receiving element is in the form of a 2D-array so that a receiver may also recognize a reflected image. Unlike this, the scanning type LIDAR point-maps a 3D space through vertical and horizontal rotations of the laser beam. Accordingly, the scanning type LIDAR has a smaller laser light source output and a simpler receiver light receiving element structure than the flash type. Existing scanning type LIDAR has a 360° viewing angle by mechanical motor rotation.

However, since a motor for rotation is heavy and consumes a lot of power, basic mechanical LIDAR may not be used in unmanned aerial vehicles that require limited power and weight, and a mechanical rotational speed does not correspond to a rotational speed required for highway traveling of the autonomous vehicle.

An optical phase array antenna may obtain a desired output laser traveling direction by dispersing an incident laser to each antenna element through several directional couplers and modulating a phase of the dispersed laser.

In order to increase a maximum measurement distance of the LIDAR, the antenna requires higher laser power, but silicon waveguides having low laser threshold power and high linear and nonlinear losses are disadvantageous compared to silicon nitride waveguides.

The silicon nitride waveguide may easily interact with adjacent waveguides having the same propagation constant because the size of an evanescent wave in a waveguide mode increases due to a low refractive index. In order to widen a limited horizontal viewing angle of the optical phase array antenna, a distance between the antenna elements needs to be close to a distance equal to half of a wavelength, but as the distance between the antenna elements is closer, a desired output phase distribution is not obtained due to a cross-talk between the adjacent elements.

In the case of LIDAR for the purpose of mounting in an autonomous vehicle, since it is important for the safety of occupants and pedestrians to operate normally without being affected by temperature changes (−40 to 85° C.) in the vehicle, it is difficult to use a phase change due to local heating capable of being used for silicon nitride waveguides.

Due to a process on a wafer, a planar optical element hardly has a clear spatial directionality because a signal transmitted through the waveguide is emitted in a similar ratio to the upper and lower ends of a chip due to vertical refractive index symmetry. In addition, the signal which has been emitted from the lower end of the chip is reflected upward from a boundary surface of the lower end and interferes with the signal emitted from the upper end to generate unwanted noise.

As a prior art related to the optical phase array antenna, in Korea Patent Registration No. 10-1924890 by the present applicant, there are disclosed ‘an optical phase array antenna and LIDAR including the same’. The prior art discloses a structure formed by changing the height of an antenna element waveguide of a light output unit and having a plurality of diffraction gratings spaced apart from each other at a higher height of the antenna element waveguide. Through the structure, it is possible to output the incident laser in a desired direction without using a mechanical driving device, and there is an advantage in minimizing the influence of external environment changes.

However, in recent years, the need for an optical phase array antenna with more improved directionality is increasing.

The above-described technical configuration is the background art for helping in the understanding of the present invention, and does not mean a conventional technology widely known in the art to which the present invention pertains.

### SUMMARY OF THE INVENTION

The present disclosure has been made to solve the above problems.

First, an object of the present disclosure is to provide an optical phase array antenna structure for developing LIDAR which is lighter, cheaper, and easier mass-produced than the related art by replacing the conventional mechanical rotation by developing LIDAR for autonomous driving and unmanned aerial vehicles based on an optical phase array antenna.

Second, an object of the present disclosure is to provide an optical phase array antenna structure with improved directionality and reduced perturbation strength compared to the related art.

Third, an object of the present disclosure is to provide an optical phase array antenna structure with an increased noise-to-signal by changing a structure of the optical phase array antenna that can be manufactured with CMOS semiconductor process technology, and has a maximum output of 2 W or more, a horizontal viewing angle of 120° or higher and a vertical viewing angle of 20° or higher.

According to an embodiment of the present disclosure, there is provided an optical phase array antenna including a coupling unit for receiving light from a light source, a light distribution unit for distributing light propagated from the coupling unit to a plurality of optical paths, a phase modulation unit for modulating a phase of the light distributed from the light distribution unit, and a light output unit that outputs the light modulated by the phase modulation unit, and includes an antenna element waveguide extending at a predetermined length through which the light propagates, and a clad layer formed to surround the antenna element waveguide, in which the antenna element waveguide has a first recessed portion recessed downward with respect to an upper surface thereof, and the clad layer has a second recessed portion recessed downward with respect to an upper surface thereof at a position adjacent to the first recessed portion.

The clad layer may be formed so that the second recessed portion may be opposed to a portion of the remaining area except for the first recessed portion of the antenna element waveguide, and the second recessed portion may be formed at a position spaced apart from the first recessed portion along a longitudinal direction of the antenna element waveguide.

The first recessed portion may be formed to have a predetermined width from one end to the other end based on the longitudinal direction of the antenna element waveguide, and the second recessed portion may be formed to have a predetermined width from one end to the other end based on the longitudinal direction of the antenna element waveguide, wherein the other end may be formed to be spaced apart from the other end of the first recessed portion by a predetermined offset distance along the longitudinal direction of the corresponding antenna element waveguide.

The offset distance may be close to 0.3 μm.

The second recessed portion may be formed to have a width corresponding to the width of the first recessed portion based on the longitudinal direction of the antenna element waveguide.

The second recessed portion may be formed to be recessed downward into the upper surface of the clad layer at a predetermined depth so that the bottom surface is adjacent to the upper surface of the antenna element waveguide.

A plurality of first recessed portions may be formed to be spaced apart from each other along the longitudinal direction of the antenna element waveguide.

A plurality of second recessed portions may be formed in the corresponding clad layer to be spaced apart from each other along the longitudinal direction of the antenna element waveguide.

The first recessed portions may be formed to be spaced apart from each other by a length corresponding to the longitudinal width of the antenna element waveguide.

The light output unit may be configured in a state in which a lower layer and an upper layer are stacked vertically on an upper portion of a base layer, the first recessed portion may be formed by etching an upper portion of the lower layer, and the second recessed portion may be formed by etching an upper portion of the upper layer.

According to another embodiment of the present disclosure, there is provided a method for processing the light output unit of the optical phase array antenna including (a) preparing a silicon-on-insulator (SOI) in which first to third layers are stacked (S110), (b) etching the third layer to form the first recessed portion on an upper surface of the third layer (S120), (c) depositing a fourth layer on the upper portion of the third layer etched in step (b) (S130), and (d) etching the upper surface of the fourth layer to form the second recessed portion on the fourth layer (S140), in which the lower layer is the third layer in step (b), and the upper layer is the fourth layer in step (d).

The third layer may be made of silicon nitride (Si₃N₄), and the fourth layer may be made of silicon dioxide (SiO₂).

After step (a) (S110) and before step (b) (S120), the method may further include (a1) coating an electron resist (ER) on the third layer to form the first recessed portion (S111), and (a2) irradiating an electron-beam (E-Beam) to a predetermined portion of the electron resist coated in step (a1), wherein the electron resist is etched in a shape corresponding to the first recessed portion (S112), in which in step (b), the third layer may be etched using the shape of the electron resist according to step (a2).

After step (c) (S130) and before step (d) (S140), the method may further include (c1) coating an electron resist (ER) on the fourth layer to form the second recessed portion (S131), and (c2) irradiating an electron-beam (E-Beam) to a predetermined portion of the electron resist coated in step (c1), wherein the electron resist is etched in a shape corresponding to the second recessed portion (S132), in which in step (d), the fourth layer may be etched using the shape of the electron resist according to step (c2).

According to yet another embodiment of the present disclosure, there is provided LIDAR including an optical phase array antenna including a light source, the optical phase array antenna according to any one of claims 1 to 10, a light receiving unit for receiving light emitted from the optical phase array antenna and then reflected by an object, and a signal processing unit for processing a signal received by the light receiving unit.

According to the present disclosure, it is expected not only to be used as a key element of vehicle LIDAR sensors without requiring scanning in the future, but also to perform a role of existing CMOS sensors used to acquire 3D images.

Further, it is possible to reduce the perturbation strength and maximize the directionality by etching not only the top of the antenna element waveguide but also the upper portion of the clad layer to form gratings.

The effects of the present disclosure are not limited to the above-described effects, and it will be understood that provisional effects toe expected by technical features of the present disclosure will be apparent from the following description.

### BRIEF DESCRIPTION OF THE DRAWINGS

The patent or application file contains at least one drawing executed in color. Copies of this patent or patent application publication with color drawing (s) will be provided by the Office upon request and payment of the necessary fee.

The above and other aspects, features and other advantages of the present invention will be more clearly understood from the following detailed description taken in conjunction with the accompanying drawings, in which:

FIG. 1 is a schematic perspective view of an optical phase array antenna according to the present disclosure;

FIG. 2 is a cross-sectional view of the optical phase array antenna of FIG. 1;

FIG. 3 is a schematic view of the optical phase array antenna of FIG. 1;

FIG. 4 is a schematic view schematically illustrating a structure of the optical phase array antenna of FIG. 1;

FIG. 5 is a schematic view of a multi-mode interferometer (MMI) constituting a light distribution unit of the optical phase array antenna according to the present disclosure;

FIG. 6 is a graph of beam directionality in a Z-axis direction of the optical phase array antenna of the present disclosure and a conventional optical phase array antenna;

FIG. 7 is a graph of reflected light in a Z-axis direction of the optical phase array antenna of the present disclosure and the conventional optical phase array antenna;

FIG. 8 is a graph of perturbation strength of the optical phase array antenna of the present disclosure and the conventional optical phase array antenna;

FIG. 9 is a schematic view of an optical phase array antenna having an offset distance of 0;

FIG. 10 is a schematic view of the optical phase array antenna according to the present disclosure;

FIG. 11 is a graph of beam directionality for the optical phase array antenna according to the present disclosure depending on an offset distance;

FIG. 12 is a graph of upward transmittance and downward transmittance of the optical phase array antenna according to the present disclosure depending on an offset distance;

FIG. 13 illustrates a distribution of light energy incident along a waveguide of the optical phase array antenna of the present disclosure;

FIG. 14 illustrates a distribution of light energy incident along a waveguide of an optical phase array antenna having an offset distance of 0;

FIG. 15 illustrates a distribution of light energy incident along a waveguide of an optical phase array antenna with only upper gratings on a clad layer;

FIG. 16 illustrates a distribution of light energy incident along a waveguide of an optical phase array antenna with only lower gratings on an antenna element waveguide;

FIG. 17 is a schematic view schematically illustrating a coupler constituting a light distribution unit of the optical phase array antenna according to the present disclosure;

FIG. 18 is a schematic view schematically illustrating a state in which a metal heater is embedded in the optical phase array antenna according to the present disclosure;

FIG. 19 is a flowchart for a method for processing a light output unit of the optical phase array antenna according to the present disclosure; and

FIGS. 20 to 34 are schematic views for each step of a method for processing a light output unit of the optical phase array antenna according to the present disclosure.

### DETAILED DESCRIPTION OF THE PREFERRED EMBODIMENT

Hereinafter, an optical phase array antenna based on an optical waveguide type with a hybrid grating structure according to the present disclosure will be described with reference to drawings. In the present disclosure, ‘one direction’ is illustrated as an ‘X-axis direction’ in the drawings, and means a longitudinal direction of the optical phase array antenna according to the present disclosure. In addition, a ‘height direction’ is illustrated as a ‘Z-axis direction’ based on the drawings. However, the directions defined herein are defined for convenience of understanding, and the application of the present disclosure is not limited to the directions.

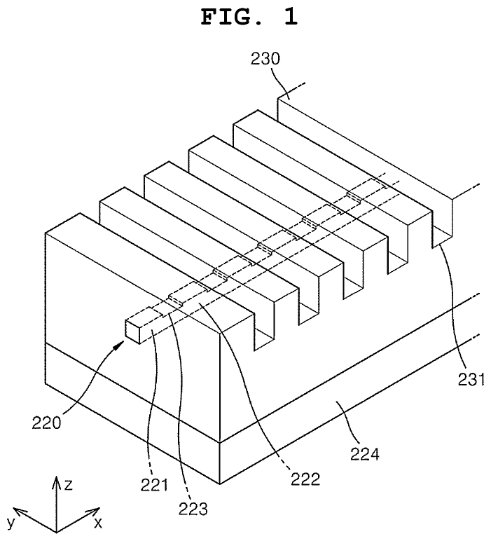

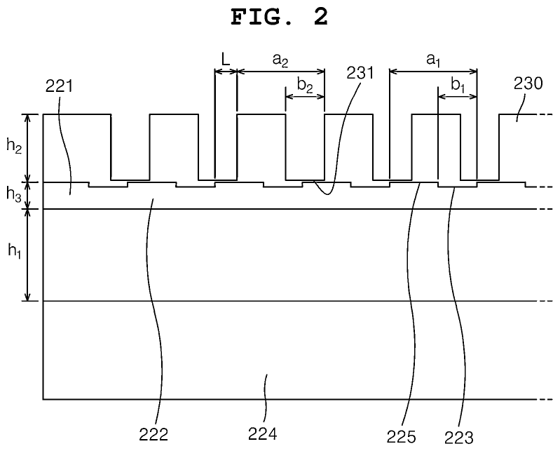

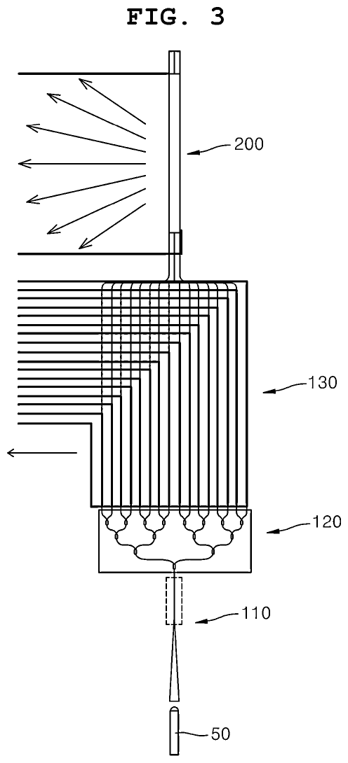

Referring to FIGS. 1 and 2, an optical phase array antenna 100 based on an optical waveguide type with a hybrid grating structure according to the present disclosure will be described, and the overall configuration will refer to FIGS. 3 and 4 together.

The optical phase array antenna 100 based on the optical waveguide type with the hybrid grating structure according to the present disclosure includes a coupling unit 110, a light distribution unit 120, a phase modulation unit 130 and a light output unit 200.

A laser transmission module of LIDAR may be constituted by including the optical phase array antenna 100 and a light source 50 supplying a laser beam to the light distribution unit 120 of the optical phase array antenna 100. Meanwhile, the LIDAR according to the present disclosure may further include a laser reception module for receiving the reflected light after light emitted from the laser transmission module to the outside is reflected on an object.

A laser generator for supplying the laser beam to the light distribution unit 120 is applied as the light source 50. Preferably, the laser generator may change the wavelength of the generated laser, and as an example, the laser generator may be a tunable laser diode. According to a change in wavelength of the laser beam supplied to the optical phase array antenna 100, the laser beam output to the outside from the optical phase array antenna 100 may be rotated in one direction. Light generated from the light source 50 is input to the coupling unit 110 of the optical phase array antenna 100.

Meanwhile, the laser reception module includes a light receiving unit for receiving light emitted from the optical phase array antenna 100 and then reflected by an object and a signal processing unit for processing a signal received by the light receiving unit. Here, since the light receiving unit and the signal processing unit are applied with the laser reception module constituting conventional LIDAR, a detailed description thereof will be omitted.

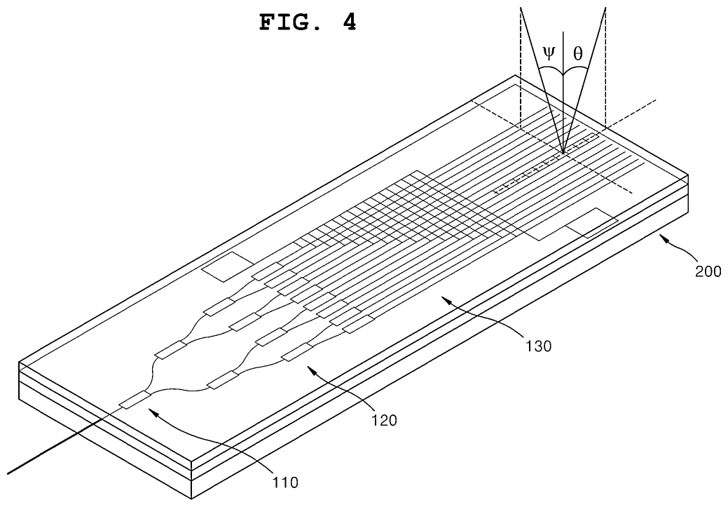

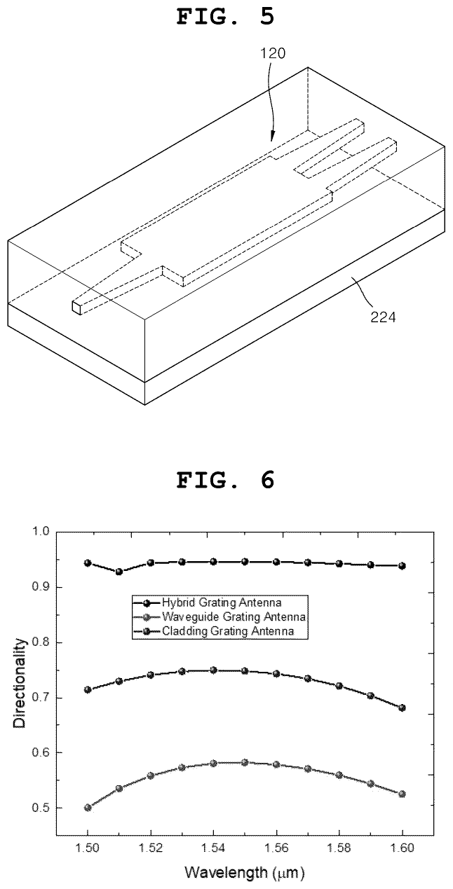

Referring to FIGS. 3 and 4, the light distribution unit 120 splits and transmits the light input to the coupling unit 110 into a plurality of light paths, that is, a plurality of antenna element waveguides. The light distribution unit 120 may be constituted by a plurality of couplers. As a coupler constituting the light distribution unit 120, a multi-mode interferometer (MMI), a Y-junction coupler, a directional coupler, or the like may be used. Here, the multi-mode interferometer is a multi-mode interferometer called MMI, which is illustrated in FIG. 5.

The phase modulation unit 130 modulates a phase of the light distributed from the light distribution unit 120 to each antenna element waveguide. That is, since the phase of the light transmitted through the antenna element waveguide is modulated, a direction of the laser beam output from the light output unit 200 may be rotated around an X-axis as the phase of light is modulated in the phase modulation unit 130. Although not specifically illustrated in the drawings of the present disclosure, the phase modulation unit 130 may adopt a method of forming an electric field by applying a potential using an electrode, and as a result, modulating the phase of the light. However, in addition to the method, it is specified that any method for modulating the phase of the light may be applied. A structure required for the phase modulation unit 130 is stacked in the order of silicon oxide, silicon nitride, silicon oxide, and silicon from the top, and a silicon nitride waveguide is surrounded by silicon oxide, and gratings are formed by etching the silicon nitride waveguide and an upper silicon oxide layer.

At this time, since the upper silicon nitride has a low refractive index of about 2, it is preferable to have a thickness of 500 nm or more for proper mode confinement.

The light output unit 200 maintains the phase distribution modulated by the phase modulation unit 130 and outputs the laser beam upward. Referring to FIGS. 3 and 4, the light output unit 200 outputs the laser beam in a Z-axis direction in an X-Y plane, and an output direction of the laser beam output from the light output unit 200 is steered according to the wavelength of the laser beam input to the light distribution unit 120 and the phase modulated in the phase modulation unit 130.

In this regard, referring to FIG. 4, an emission angle θ from a forward direction to a vertical direction of the light output through the light output unit 200 may be controlled according to Equation 1 below.

$$Sin ( θ ) = \frac{{n}_{eff} - \frac{λ}{Λ}}{{n}_{background}} \qquad [ Equation 1 ]$$

As can be seen through Equation 1 above, an effective refractive index n_{eff} of the mode, a background refractive index n_{background}, an operating wavelength λ, and a pitch Λ of a first recessed portion 223 or a second recessed portion 231 to be described below are input, the emission angle θ may be calculated.

In the light output unit 200, since an optimized waveguide width needs to be used to decrease a distance between the antenna element waveguides 220, but is a large width enough to make an evanescent wave small, it is necessary to compensate for a distance between elements that become closer due to the large width. A diffraction grating in which the thickness of a silicon nitride layer of a hybrid waveguide is periodically changed is used for directional emission to the top of the antenna element. At this time, the thickness change of the silicon nitride layer allows a phase change experienced in thin and thick parts to satisfy constructive interference at the top and destructive interference at the bottom to emit the light in an upward direction, and the thicknesses of silicon oxide thin films of the upper and lower layers surrounding the hybrid waveguide are close to a multiple of half the wavelength so as to satisfy constructive interference.

In addition, a maximum value of the thickness of silicon nitride periodically changed to eliminate vertical refractive index symmetry may be thicker than that of the receiver or the phase modulation unit 130.

As the shape of the diffraction grating of the antenna element, a width change of the hybrid waveguide may be used, and when the width changes while crossing left and right, the distance between adjacent waveguides may be kept constant, and when the width changes while crossing the surrounding waveguides, an effective refractive index of the mode for each waveguide is varied. Accordingly, the strength of mode coupling is weakened to reduce the strength of crosstalk of propagated signals. In addition, when a large amount of output is desired at a short distance, the antenna element waveguides 220 may be discontinuously arranged.

Referring back to FIGS. 1 and 2, a specific structure of the optical phase array antenna 100 according to the present disclosure will be described. Layers constituting the optical phase array antenna 100 will be separately described below.

The light output unit 200 of the optical phase array antenna 100 according to the present disclosure outputs the light modulated by the phase modulation unit 130, and includes an antenna element waveguide 220 extending at a predetermined length along one direction (X-axis direction) through which the corresponding light propagates, and a clad layer 230 formed to surround the antenna element waveguide 220.

The antenna element waveguide 220 may be divided into a flat waveguide part 221 and a grating antenna part 222. Here, both the flat waveguide part 221 and the grating antenna part 222 are positioned on an extension line in one direction, and the flat waveguide part 221 and the grating antenna part 222 are sequentially disposed based on one direction.

The flat waveguide part 221 is formed to have a predetermined length, and the grating antenna part 222 is formed so that a plurality of first recessed portions 223 are spaced apart from each other along one direction. In addition, the flat waveguide part 221 and the grating antenna part 222 may be formed in a bar shape made of silicon nitride (Si₃N₄). The antenna element waveguide 220 of the present disclosure is disposed on a substrate 224 called a wafer, and is surrounded and buried by the clad layer 230 made of silicon (SiO₂). Here, the upper and lower surfaces of the flat waveguide part 221 and the grating antenna part 222 may be configured at the same height, and the corresponding height of 0.56 μm is applied. In addition, the flat waveguide part 221 and the grating antenna part 222 are formed to have a width of 2 μm in a Y-axis direction. Meanwhile, a distance from the upper surfaces of the flat waveguide part 221 and the grating antenna part 222 to the upper surface of the clad layer 230 and a distance from the lower surfaces thereof to the substrate 224 may be selected to optimal values according to a designer's selection.

As described above, the grating antenna part 222 has a plurality of first recessed portions 223. The first recessed portions 223 are formed to be recessed downward at a predetermined depth with respect to the upper surface of the antenna element waveguide 220. Herein, it is preferred that the first recessed portion 223 is recessed at a depth of 0.07 μm with respect to the upper surface of the antenna element waveguide 220. In addition, the first recessed portion 223 is formed to have a width corresponding to the width of the antenna element waveguide 220 based on the Y-axis direction.

The first recessed portion 223 is formed to have a predetermined width from one end to the other end in the longitudinal direction, that is, one direction of the antenna element waveguide 220, and a plurality of first recessed portions 223 are formed to be spaced part from each other in the longitudinal direction, that is, one direction of the antenna element waveguide 220. That is, the first recessed portions 223 and first protruding portions 225 between the first recessed portions 223 are alternately formed along the longitudinal direction of the waveguide of the antenna element. At this time, the first protruding portions 225 and the first recessed portions 223 are formed repeatedly at a predetermined period a₁. Here, the corresponding period is 0.85 μm, and it is preferable to form the first recessed portions to have a width b₁ of 0.425 μm, which is half of the corresponding period, but is not limited thereto, and various values may be applied according to specifications of an antenna to be manufactured.

The clad layer 230 is formed to surround the antenna element waveguide 220 and is provided on the upper surface of the substrate 224. In this case, the clad layer 230 may support the antenna element waveguide 220 to be spaced upward from the substrate 224. Here, the clad layer 230 is formed so that the height from the lower surface thereof to the lower surface of the antenna element waveguide 220 is greater than the height from the upper surface thereof to the upper surface of the antenna element waveguide 220. That is, a height h1 from the lower surface of the clad layer 230 to the lower surface of the antenna element waveguide 220 is 3.22 μm, and a height h2 from the upper surface of the clad layer 230 to the upper surface of the antenna element waveguide 220 is 1.34 μm, but the heights are not limited thereto, and may be variously set according to a type or size of the LIDAR. In addition, it is preferred that the clad layer 230 is formed to have a larger width than the width of the antenna element waveguide 220 based on the Y-axis direction.

Meanwhile, in the clad layer 230, the second recessed portion 231 recessed downward based on the upper surface is formed at a position adjacent to the first recessed portion 223 of the antenna element waveguide 220. Here, the second recessed portion 231 is preferably formed to be recessed downward at a depth of 1.3 μm with respect to the upper surface of the clad layer 230 so that the bottom surface is adjacent to the upper surface of the antenna element waveguide 220.

In addition, the second recessed portion 231 is formed to have a predetermined width from one end to the other end based on the longitudinal direction of the antenna element waveguide 220, and a plurality of second recessed portions 231 are formed to be spaced apart from each other along the longitudinal direction, that is, one direction of the antenna element waveguide 220. That is, the second recessed portions 231 and second protruding portions 232 between the second recessed portions 231 are alternately formed along the longitudinal direction of the waveguide of the antenna element. At this time, the second protruding portions 232 and the second recessed portions 231 are formed repeatedly at a predetermined period a₂. Here, the corresponding period is 0.85 μm, and it is preferable to form the second recessed portions to have a width b₂ of 0.425 μm, which is half of the corresponding period, but is not limited thereto, and various values may be applied according to specifications of an antenna to be manufactured.

In addition, the clad layer 230 is formed so that the second recessed portion 231 may be opposed to a portion of the remaining area except for the first recessed portion 223 of the antenna element waveguide 220, and the second recessed portion 231 may be formed at a position spaced apart from the first recessed portion 223 along the longitudinal direction, that is, one direction of the antenna element waveguide 220. That is, the second recessed portion 231 is formed so that the other end is spaced apart from the other end of the first recessed portion 223 backward by a predetermined offset distance L along the longitudinal direction, that is, one direction of the antenna element waveguide 220. Here, the offset distance is preferably close to 0.3 μm. In addition, the second recessed portion 231 is formed to have a width corresponding to the width of the clad layer 230 based on the Y-axis direction.

In addition, a plurality of second recessed portions 231 are formed to be spaced apart from each other along the longitudinal direction, that is, one direction of the antenna element waveguide 220. At this time, it is preferable that the second recessed portions 231 are spaced apart from each other by a separation distance corresponding to the longitudinal width of the first recessed portion 223.

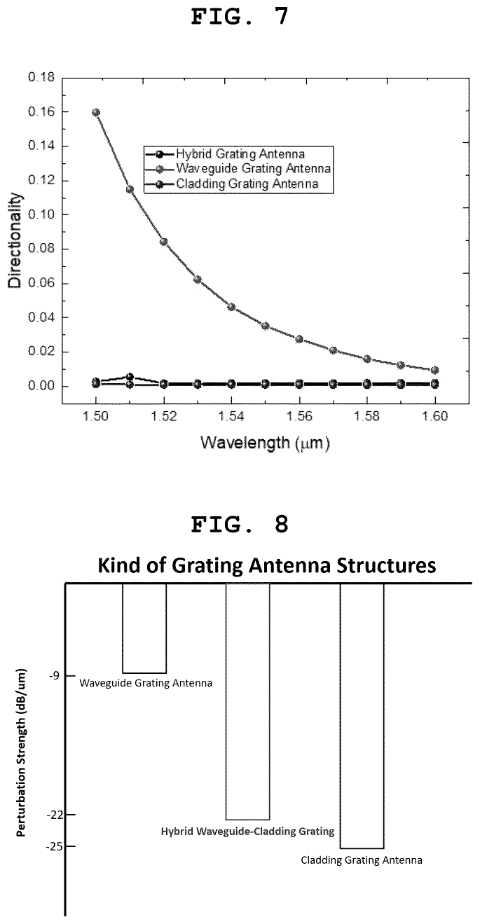

Meanwhile, FIGS. 6 and 7 show graphs for beam directionality in a Z-axis direction and reflected light of the optical phase array antenna 100 of the present disclosure and a conventional optical phase array antenna 100. In the drawings, a ‘Hybrid Grating Antenna’ is the optical phase array antenna 100 of the present disclosure, a ‘Wave Grating Antenna’ is an antenna provided with a pattern etched on a conventional waveguide, and a ‘Cladding Grating Antenna’ is an antenna provided with a pattern etched on a conventional clad layer 230. Referring to the drawings, in terms of the beam directionality, the optical phase array antenna 100 of the present disclosure shows higher efficiency (directionality=95%) than the antenna (directionality=60%) provided with the pattern etched on the conventional waveguide and the antenna (directionality=70%) provided with the pattern etched on the clad layer 230. In addition, it can be seen that the optical phase array antenna 100 of the present disclosure is more suitable for FMCW LiDAR due to less reflected light than the antenna provided with the pattern etched on the waveguide.

In addition, FIG. 8 illustrates a graph for perturbation strength of the optical phase array antenna 100 of the present disclosure and the conventional optical phase array antenna 100. In the drawings, a ‘Hybrid Waveguide-Cladding Grating’ is the optical phase array antenna 100 of the present disclosure, a ‘Wave Grating Antenna’ is an antenna provided with a pattern etched on a conventional waveguide, and a ‘Cladding Grating Antenna’ is an antenna provided with a pattern etched on a conventional clad layer 230. Referring to the drawings, the optical phase array antenna 100 of the present disclosure is lower than the antenna provided with the pattern etched on the conventional waveguide, which is suitable for high-resolution LIDAR applications.

As described above, the optical phase array antenna 100 according to the present disclosure enhances the upward transmittance of the antenna through strong interaction between the grating structures formed on the antenna element waveguide 220 and the clad layer 230 and suppresses the downward transmittance, thereby maximizing the directionality.

Meanwhile, the interaction strength of the two grating structures may be adjusted through a separation distance between the first recessed portion 223 and the second recessed portion 231, that is, the offset distance.

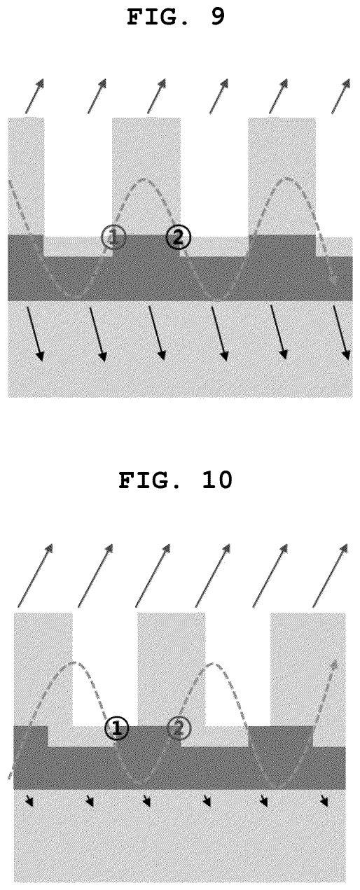

FIG. 9 illustrates a schematic diagram of an optical phase array antenna 100 having an offset distance of 0, and FIG. 10 illustrates a schematic diagram of an optical phase array antenna 100 according to the present disclosure. Referring to the drawing, in the case of the optical phase array antenna 100 having an offset distance of 0, light is directed upward at a front portion of the waveguide grating, that is, one end (portion \textcircled{1}) of the first recessed portion 223 and the light is directed downward at a rear portion of the waveguide grating, that is, the other end (portion \textcircled{2}) of the first recessed portion 223. On the contrary, in the case of the optical phase array antenna 100 of the present disclosure, as a result of the interaction of the two gratings, light is directed downward at the front portion of the waveguide grating, that is, one end (portion \textcircled{1}) of the first recessed portion 223 and the light is directed upward at the rear portion of the waveguide grating, that is, the other end (portion \textcircled{2}) of the first recessed portion 223. Accordingly, in the optical phase array antenna 100 of the present disclosure, perturbation may be minimized while the energy of incident light has a relatively high directionality according to a size of the offset distance.

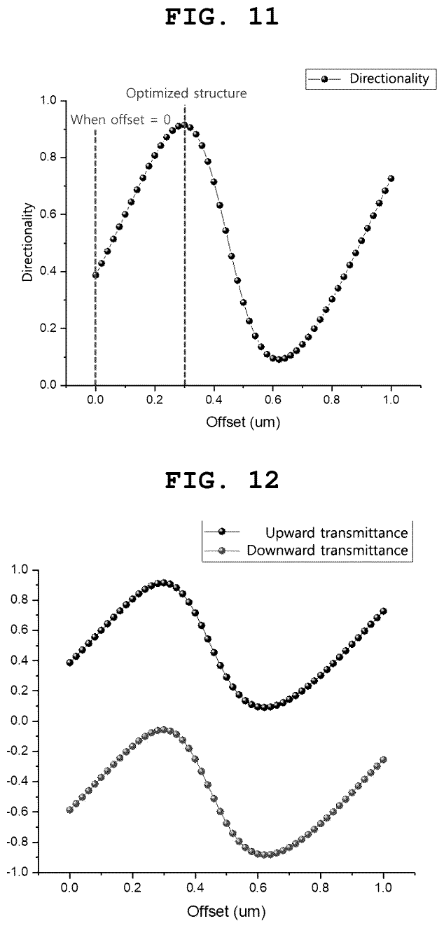

Meanwhile, FIG. 11 shows a graph of beam directionality for the optical phase array antenna 100 of the present disclosure depending on an offset distance, and FIG. 12 shows a graph of upward transmittance and downward transmittance of the optical phase array antenna 100 of the present disclosure depending on an offset distance.

Referring to the drawing, the beam directionality, upward transmittance and downward transmittance of the optical phase array antenna 100 increase as the offset distance increases, but decrease when the offset distance exceeds 0.3 μm. Therefore, it is preferable that the offset distance between the first recessed portion 223 and the second recessed portion 231 is 0.3 μm or less, that is, close to 0.3 μm.

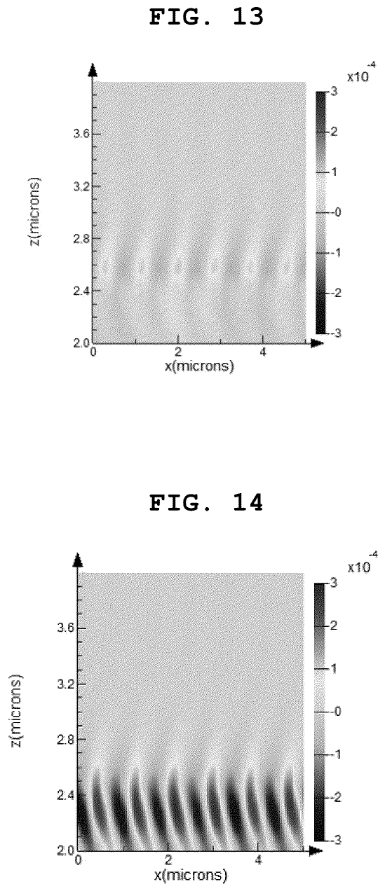

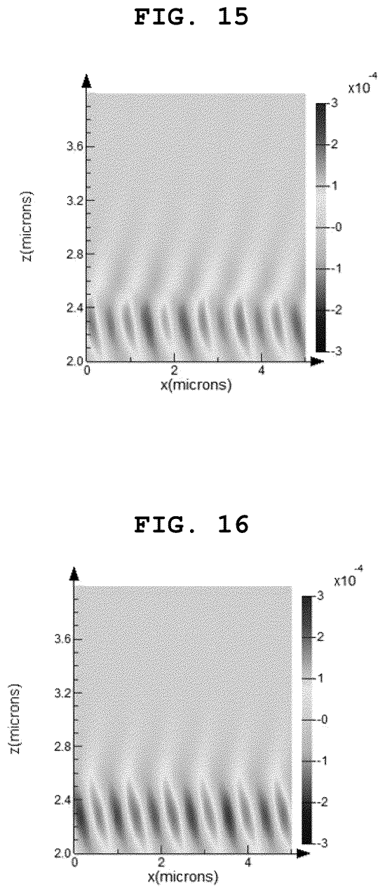

Meanwhile, FIG. 13 illustrates a distribution of light energy incident along the waveguide of the optical phase array antenna 100 of the present disclosure, FIG. 14 illustrates a distribution of light energy incident along the waveguide of the optical phase array antenna 100 having an offset distance of 0, FIG. 15 illustrates a distribution of light energy incident along the waveguide of the optical phase array antenna 100 with only the second recessed portions 231, that is, the upper gratings on the clad layer 230, and FIG. 16 illustrates a distribution of light energy incident along the waveguide of the optical phase array antenna 100 with only the first recessed portions 223, that is, the lower gratings on the antenna element waveguide 220. Referring to the drawings, it can be seen that the optical phase array antenna 100 of the present disclosure has relatively weak perturbation and a small beam size compared to other antennas to be suitable for high-resolution long-range LIDAR.

Meanwhile, the light output unit 200 of the optical phase array antenna 100 of the present disclosure is configured in a state in which a lower layer and an upper layer are stacked vertically on an upper portion of a base layer, the first recessed portion 223 is formed by etching an upper portion of the lower layer, and the second recessed portion 231 is formed by etching an upper portion of the upper layer.

FIG. 17 schematically illustrates a coupler 121 constituting the optical distribution unit 120 of the optical phase array antenna 100 according to the present disclosure. As described above, when the light source 50 is configured with a laser diode, since a mode diameter of the laser beam output from the laser diode is larger than a mode diameter of the waveguide of the optical phase array antenna 100, the coupling unit 110 is designed to have a reverse taper shape (in which the width of the portion where the laser beam is input is narrow and the width increases in the direction of the phase modulation unit 130) in order to reduce the mode diameter.

FIG. 5 schematically illustrates a multi-mode interferometer constituting the optical distribution unit 120 of the optical phase array antenna 100 according to the present disclosure. The multi-mode interferometer (MMI) is a device used to split light traveling along the antenna element waveguide. Similarly to an optical fiber-to-chip coupler, mode matching between waveguides is important, and a rhombic shape may be used. At this time, a mode means a state in which light may travel within the waveguide (optical fiber) without energy loss, and the shape of the mode varies depending on the material and shape of the waveguide and the characteristics of light. When the mode of light incident on the waveguide does not match the mode of the waveguide, the light is quickly attenuated and disappears.

FIG. 18 schematically illustrates the phase modulation unit 130 in which a metal heater 131 is embedded in the optical phase array antenna 100 according to the present disclosure. A micro heater that changes the phase of each light wave by changing the effective refractive index of the antenna element waveguide 220 is heated by Joule heating due to the resistance of the electrode when a current flows through a metal electrode with a micrometer-sized width, but configured to enable phase modulation using such a thermo-optical phenomenon. For reference, one of key elements of the optical phase array antenna 100 is a diffraction grating-based waveguide grating antenna (WGA) that functions to emit beams in a vertical direction of the chip, and a diffraction grating structure optimized for directionality control of the WGA is developed and manufactured to include a micro-heater for controlling a divergence angle.

Meanwhile, FIG. 19 illustrates a flowchart for a method for processing the light output unit 200 of the optical phase array antenna 100 according to the present disclosure.

Referring to the drawing, the method for processing the light output unit 200 of the optical phase array antenna includes steps S110 to S140.

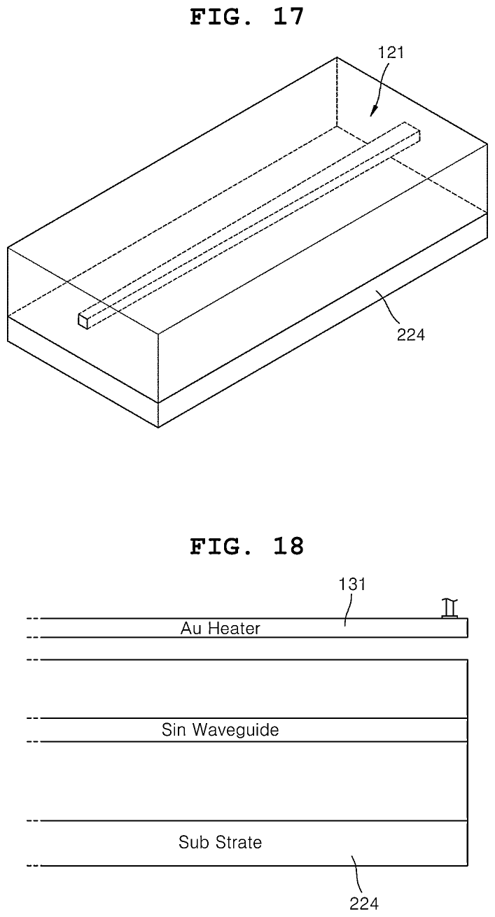

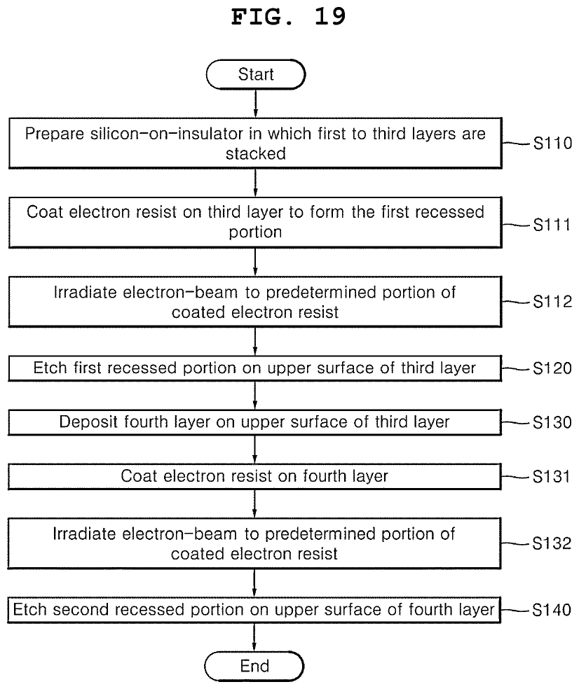

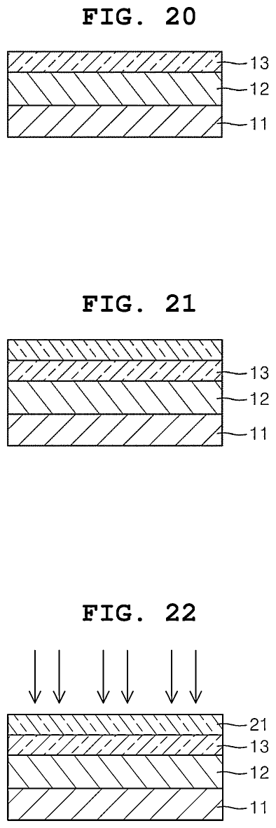

Step S110 is a step of preparing a silicon-on-insulator (SOI) in which first to third layers 11, 12, and 13 are stacked as illustrated in FIG. 20. Here, it is preferred that the first layer 11 is formed of Si, the second layer 12 is formed of SiO₂, and the third layer is formed of Si₃N₄.

Meanwhile, steps S111 and S112 are further included after step S110 and before step S120.

Step S111 is a step of coating an electron resist (ER) 21 on the third layer 13 to form the first recessed portion 223 as illustrated in FIG. 21. Here, it is preferred to coat the corresponding electron resist 21 so as to cover the entire upper surface of the third layer 13.

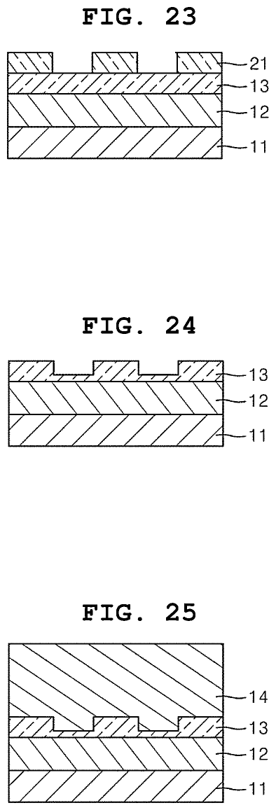

Step S112 is a step of irradiating an electron-beam (E-Beam) to a predetermined portion of the electron resist 21 coated in step S111 as illustrated in FIG. 22, and a step of etching the electron resist 21 in a shape corresponding to the first recessed portion 223 as illustrated in FIG. 23. In particular, in step S120, the third layer 13 is etched using the shape of the electron resist 21 according to step S112.

Step S120 is a step of etching the third layer 13 to form the first recessed portion 223 on the upper surface of the third layer 13 as illustrated in FIG. 24. The first recessed portion 223 is formed by etching a part of the upper side of the third layer 13 exposed to the outside through the etched portion of the electron resist 21 processed in step S112, and when the formation of the first recessed portion 223 is completed, the corresponding electron resist 21 is removed from the third layer 13. Here, the third layer 13 is the lower layer.

Step S130 is a step of depositing a fourth layer 14 on the upper portion of the third layer 13 etched in step S120, as illustrated in FIG. 25. Here, the fourth layer 14 is preferably made of silicon dioxide (SiO₂). First, the fourth layer 14 is deposited on the upper portion of the third layer 13 at a height of 1.34 μm or more, and then the fourth layer 14 is processed to have a height of 1.34 μm through a polishing operation. Through the polishing operation, a structure of the fourth layer 14 having a flat upper surface may be obtained.

Meanwhile, steps S131 and S132 are further included after step S130 and before step S140.

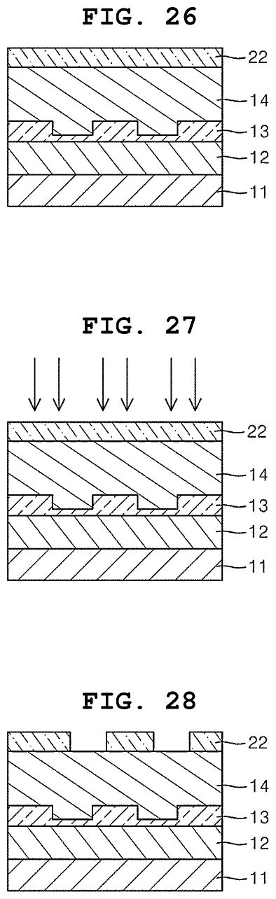

Step S131 is a step of coating an electron resist (ER) 22 on the fourth layer 14 to form the second recessed portion 231 as illustrated in FIG. 26. Here, it is preferred to coat the corresponding electron resist 22 so as to cover the entire upper surface of the fourth layer 14.

Step S132 is a step of irradiating an electron-beam (E-Beam) to a predetermined portion of the electron resist 22 coated in step S131 as illustrated in FIG. 27, and a step of etching the electron resist 22 in a shape corresponding to the second recessed portion 231 as illustrated in FIG. 28. In particular, in step S140, the fourth layer 14 is etched using the shape of the electron resist 22 according to step S132.

Step S140 is a step of etching the upper surface of the fourth layer 14 to form the second recessed portion 231 on the fourth layer 14 as illustrated in FIG. 29. The second recessed portion 231 is formed by etching a part of the upper side of the fourth layer 14 exposed to the outside through the etched portion of the electron resist 22 processed in step S132, and when the formation of the second recessed portion 231 is completed, the corresponding electron resist 22 is removed from the fourth layer 14. Here, the fourth layer 14 is the upper layer.

Meanwhile, when step S140 is completed, a pattern forming step of forming a predetermined circuit pattern on the upper surface of the fourth layer 14 is further included.

In the pattern forming step, as illustrated in FIG. 30, a photo resist 23 is coated on the upper surface of the fourth layer 14 on which the second recessed portions 231 are formed. At this time, it is preferable to perform a planarization operation so that the upper surface of the photo resist 23 is flat.

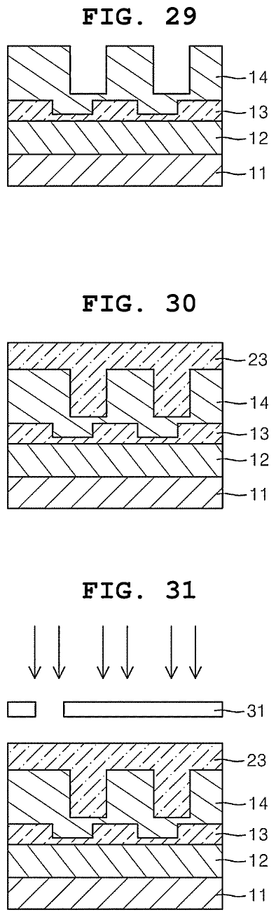

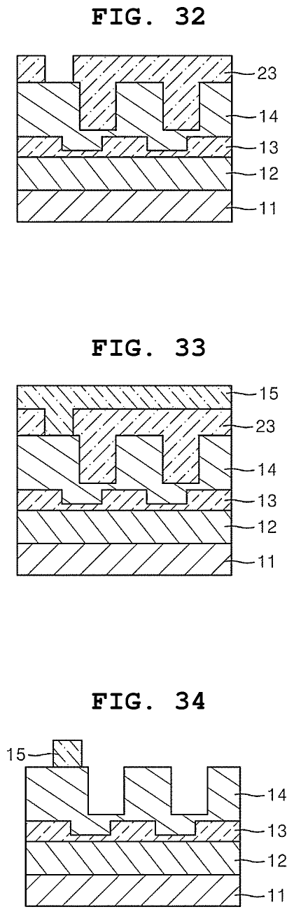

Next, as illustrated in FIG. 31, a mask 31 having a light-transmitting portion formed in a shape corresponding to the circuit pattern is set on the upper side of the photo resist 23, and then light is irradiated onto the upper portion of the mask 31. Here, only light passing through the light-transmitting portion of the mask 31 reaches the photo resist 23, and a portion of the photo resist 23 corresponding to the light-transmitting portion is etched by the corresponding light as illustrated in FIG. 32. Next, as illustrated in FIG. 33, a fifth layer 15 is formed on the photo resist 23. At this time, the fifth layer 15 may be made of Au, Cr, etc., which is a material capable of generating heat by allowing a current to flow, but is preferably made of Ti having high electrical resistivity.

When the deposition of the fifth layer 15 is completed, the fifth layer 15 exposed above the photo resist 23 is removed, and then the photo resist 23 is removed from the fourth layer 14. At this time, as illustrated in FIG. 34, apart of the fifth layer 15 filled in the etched portion of the photo resist 23 remains on the fourth layer 14 to form a circuit pattern.

The description of the presented embodiments is provided so that those skilled in the art of the present disclosure use or implement the present disclosure. Various modifications of the exemplary embodiments will be apparent to those skilled in the art and general principles defined herein can be applied to other exemplary embodiments without departing from the scope of the present disclosure. Therefore, the present disclosure is not limited to the exemplary embodiments presented herein, but should be analyzed within the widest range which is coherent with the principles and new features presented herein.

What is claimed is:

1. An optical phase array antenna comprising:
a coupling unit for receiving light from a light source;
a light distribution unit for distributing light propagated from the coupling unit to a plurality of optical paths;
a phase modulation unit for modulating a phase of the light distributed from the light distribution unit; and
a light output unit that outputs the light modulated by the phase modulation unit, and includes an antenna element waveguide extending at a predetermined length through which the light propagates, and a clad layer formed to surround the antenna element waveguide,
wherein the antenna element waveguide has a first recessed portion recessed downward with respect to an upper surface thereof, and
the clad layer has a second recessed portion recessed downward with respect to an upper surface thereof at a position adjacent to the first recessed portion.

2. The optical phase array antenna of claim 1, wherein the clad layer is formed so that the second recessed portion may be opposed to a portion of the remaining area except for the first recessed portion of the antenna element waveguide, and the second recessed portion is formed at a position spaced apart from the first recessed portion along a longitudinal direction of the antenna element waveguide.

3. The optical phase array antenna of claim 1, wherein the first recessed portion is formed to have a predetermined width from one end to the other end based on the longitudinal direction of the antenna element waveguide, and
the second recessed portion is formed to have a predetermined width from one end to the other end based on the longitudinal direction of the antenna element waveguide, wherein the other end is formed to be spaced apart from the other end of the first recessed portion by a predetermined offset distance along the longitudinal direction of the corresponding antenna element waveguide.

4. The optical phase array antenna of claim 3, wherein the offset distance is 0.3 μm or less.

5. The optical phase array antenna of claim 3, wherein the second recessed portion is formed to have a width corresponding to the width of the first recessed portion based on the longitudinal direction of the antenna element waveguide.

6. The optical phase array antenna of claim 3, wherein the second recessed portion is formed to be recessed downward into the upper surface of the clad layer at a predetermined depth so that the bottom surface is adjacent to the upper surface of the antenna element waveguide.

7. The optical phase array antenna of claim 1, wherein a plurality of first recessed portions are formed to be spaced apart from each other along the longitudinal direction of the antenna element waveguide.

8. The optical phase array antenna of claim 1, wherein a plurality of second recessed portions are formed in the corresponding clad layer to be spaced apart from each other along the longitudinal direction of the antenna element waveguide.

9. The optical phase array antenna of claim 7, wherein the first recessed portions are formed to be spaced apart from each other by a length corresponding to the longitudinal width of the antenna element waveguide.

10. The optical phase array antenna of claim 1, wherein the light output unit is configured in a state in which a lower layer and an upper layer are stacked vertically on an upper portion of a base layer,
the first recessed portion is formed by etching an upper portion of the lower layer, and
the second recessed portion is formed by etching an upper portion of the upper layer.

11. A method for processing the light output unit of the optical phase array antenna of claim. 10, the method comprising:
(a) preparing a silicon-on-insulator (SOI) in which first to third layers are stacked (S110);
(b) etching the third layer to form the first recessed portion on an upper surface of the third layer (S120);
(c) depositing a fourth layer on the upper portion of the third layer etched in step (b) (S130); and
(d) etching the upper surface of the fourth layer to form the second recessed portion on the fourth layer (S140),
wherein the lower layer is the third layer in step (b), and
the upper layer is the fourth layer in step (d).

12. The method of claim 11, wherein the third layer is made of silicon nitride (Si₃N₄), and
the fourth layer is made of silicon dioxide (SiO₂).

13. The method of claim 11, further comprising:
after step (a) (S110) and before step (b) (S120),
(a1) coating an electron resist (ER) on the third layer to form the first recessed portion (S111); and
(a2) irradiating an electron-beam (E-Beam) to a predetermined portion of the electron resist coated in step (a1), wherein the electron resist is etched in a shape corresponding to the first recessed portion (S112),
wherein in step (b), the third layer is etched using the shape of the electron resist according to step (a2).

14. The method of claim 11, further comprising:
after step (c) (S130) and before step (d) (S140),
(c1) coating an electron resist (ER) on the fourth layer to form the second recessed portion (S131); and
(c2) irradiating an electron-beam (E-Beam) to a predetermined portion of the electron resist coated in step (c1), wherein the electron resist is etched in a shape corresponding to the second recessed portion (S132),
wherein in step (d), the fourth layer is etched using the shape of the electron resist according to step (c2).

15. LIDAR comprising:
a light source;
the optical phase array antenna according to claim 1;
a light receiving unit for receiving light emitted from the optical phase array antenna and then reflected by an object; and
a signal processing unit for processing a signal received by the light receiving unit.
